(19) United States
(12) Patent Application Publication
(10) Pub. No.: US 2016/0078923 A1
(43) Pub. Date: Mar. 17, 2016

(54) SEMICONDUCTOR MEMORY DEVICE

(71) Applicant: KABUSHIKI KAISHA TOSHIBA, Tokyo (JP)

(72) Inventor: Tsuyoshi MIDORIKAWA, Yokohama Kanagawa (JP)

(21) Appl. No.: 14/630,440

(22) Filed: Feb. 24, 2015

(30) Foreign Application Priority Data
Sep. 12, 2014 (JP) 2014-186726

(51) Int. Cl. G11C 11/419

(52) U.S. Cl. CPC G11C 11/419

(57) ABSTRACT

In an embodiment, a semiconductor memory device includes a memory cell that includes a first inverter having a first input and a first output, and a second inverter having a second input connected to the first output and a second output connected to first input portion. A first bit line that is connected to the first output of the first inverter via a first transmission transistor. A second bit line is connected to the second output of the second inverter via a second transmission transistor. A first p channel MOS transistor has a drain connected to the first bit line, and a gate connected to the second bit line. A second p channel MOS transistor has a drain connected to the second bit line and a gate connected to the first bit line.

### CROSS-REFERENCE TO RELATED APPLICATION

This application is based upon and claims the benefit of priority from Japanese Patent Application No. 2014-186726, filed Sep. 12, 2014, the entire contents of which are incorporated herein by reference.

### FIELD

Embodiments described herein relate generally to a semiconductor memory device.

### BACKGROUND

A semiconductor memory device, for example, a static random access memory (SRAM) performs data reading using a bit line in a pair of bit lines. In the reading, when “High (H)” logic value data stored in a memory cell (hereinafter, referred to as SRAM cell) of an SRAM is read out, a potential of the bit line is required to be maintained at “H” level during the reading. For this reason, a circuit (hereinafter, referred to as keeper circuit) for keeping the bit line potential at “H” during the reading of data is usually provided.

Meanwhile, when “Low (L)” logic value data stored in an SRAM cell is read out, a bit line potential that has been precharged to be in an “H” state must be discharged to “Low (L)” level. However, since there is a keeper circuit, it takes some time for the bit line potential to be lowered to “L”, due to an electric current flowing from the keeper circuit. For this reason, a reading speed of the “L” data is decreased.

### DESCRIPTION OF THE DRAWINGS

FIG. 1 is a circuit diagram illustrating a configuration of a semiconductor memory device according to a first embodiment.

FIG. 2 is a timing chart illustrating a reading operation of “L” data according to the first embodiment.

FIG. 3 is a timing chart illustrating a reading operation of “H” data according to the first embodiment.

FIG. 4 is a circuit diagram illustrating a configuration of a semiconductor memory device according to a second embodiment.

### DETAILED DESCRIPTION

Embodiments provide a semiconductor memory device having a reading operation with improved speed.

According to an example embodiment, semiconductor memory device includes a memory cell. The memory cell includes a first inverter having a first input and a first output, and a second inverter having a second input connected to the first output and a second output connected to the first input. A first bit line is connected to the first output via a first transmission transistor. A second bit line is connected to the second output via a second transmission transistor. A first p channel metal-oxide-semiconductor (MOS) transistor has a drain connected to the first bit line and a gate connected to the second bit line. A second p channel metal-oxide-semiconductor (MOS) transistor has a drain connected to the second bit line and a gate connected to the first bit line.

According to an example embodiment, a semiconductor memory device includes: a memory cell that includes a first inverter including a first input portion and a first output portion, and a second inverter including a second input portion connected to the first output portion, and a second output portion connected to the first input portion; a first bit line that is connected to the first output portion of the first inverter via a first transmission transistor; a second bit line that is connected to the second output portion of the second inverter via a second transmission transistor; a first p channel MOS transistor including a drain connected to the first bit line, and a gate connected to the second bit line; and a second p channel MOS transistor including a drain connected to the second bit line, and a gate connected to the first bit line.

Hereinafter, example embodiments will be described with reference to the drawings. Herein, a static random access memory (SRAM) will be described as a specific example of a semiconductor memory device; however, other memory types may be adopted. Here, in the following description, the same reference numerals and symbols will be given to the configuration elements having the same or substantially similar function and configuration, and the repeated description will only be made as necessary.

### 1. First Embodiment

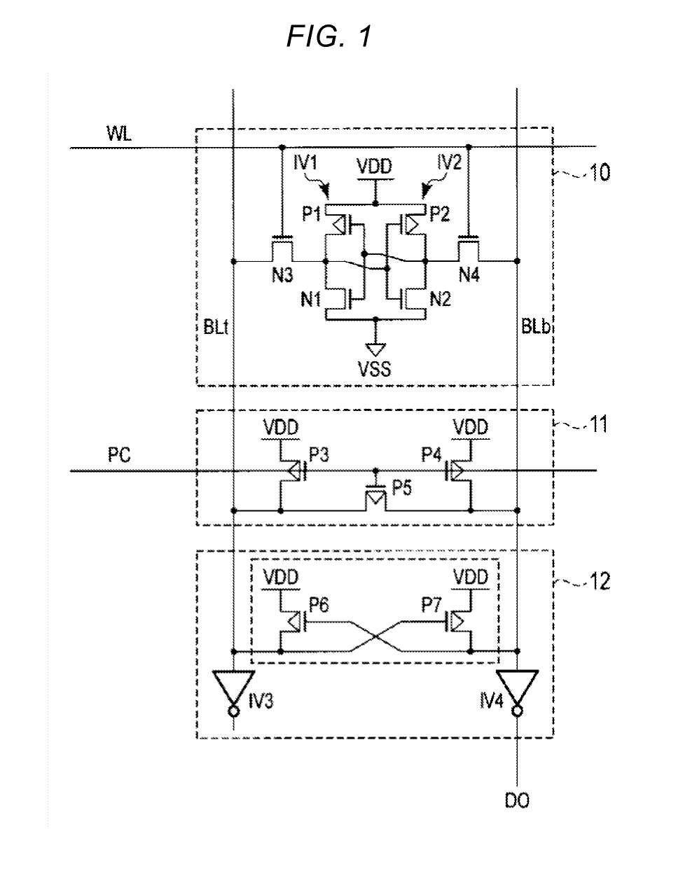

A semiconductor memory device according to a first embodiment will be described. FIG. 1 is a circuit diagram illustrating a configuration of a semiconductor memory device according to the first embodiment. As illustrated in FIG. 1, the semiconductor memory device includes an SRAM cell 10, a precharge circuit 11, and a reading circuit 12.

The SRAM cell 10 includes a first inverter IV1 that includes a p channel MOS field effect transistor (hereinafter, referred to as pMOS transistor) P1 and an n channel MOS field effect transistor (hereinafter, referred to as nMOS transistor) N1, a second inverter IV2 that includes a pMOS transistor P2 and an nMOS transistor N2, and nMOS transistors N3 and N4. The SRAM cell 10 stores data of “H” or “L” value that is determined by states of the inverters IV1 and IV2.

The inverter IV1 and the inverter IV2 have input portions and output portions that are cross-coupled to each other. That is, the output portion of the inverter IV1 is connected to the input portion of the inverter IV2, and the input portion of the inverter IV1 is connected to the output portion of the inverter IV2. Sources of the pMOS transistors P1 and P2 are connected to a power supply voltage VDD, and sources of the nMOS transistors N1 and N2 are connected to a reference voltage (for example, ground voltage) VSS.

The output portion of the inverter IV1 is connected to a first bit line BLt via a current path of the nMOS transistor N3. The output portion of the inverter IV2 is connected to a second bit line BLb via a current path of the nMOS transistor N4. The bit line BLt and the bit line BLb are an example of a bit line pair, and a signal that is complementary to a signal of the bit line BLt is supplied to the bit line BLb.

Gates of the nMOS transistors N3 and N4 are connected to a word line WL. The nMOS transistors N3 and N4 are turned on or turned off according to a potential of the word line WL, and here serve as transmission transistors.

The precharge circuit 11 includes pMOS transistors P3, P4, and P5. A drain of the pMOS transistor P3 is connected to the bit line BLt, and a drain of the pMOS transistor P4 is connected to the bit line BLb. Sources of the pMOS transistors P3 and P4 are connected to the power supply voltage VDD. A current path of the pMOS transistor P5 is connected between the bit line BLt and the bit line BLb. A precharge signal PC is input to the gates of the pMOS transistors P3, P4, and P5. If “L” is input as the precharge signal PC, the pMOS transistors P3, P4, and P5 turn to an ON state (conducting state), and the bit line BLt and the bit line BLb are precharged to “H”.

The reading circuit 12 includes pMOS transistors P6 and P7, which have gates and drains that are cross-coupled to each other, and inverters IV3 and IV4. The drain of the pMOS transistor P6 is connected to the bit line BLt and the gate of the pMOS transistor P7. The drain of the pMOS transistor P7 is connected to the bit line BLb and the gate of the pMOS transistor P6. Sources of the pMOS transistors P6 and P7 are connected to the power supply voltage VDD. Furthermore, one end of the bit line BLt is connected to the inverter IV3, and one end of the bit line BLb is connected to the inverter IV4. Then, output data DO is output from the inverter IV4. In addition, the output data DO is inverted data that is obtained by inverting the data stored in the SRAM cell 10 using the inverter IV4.

If “H” is stored in the SRAM cell 10, the bit line BLb turns to “H”, and the bit line BLt turns to “L”. In this case, the pMOS transistor P7 turns to an ON state by application of the “L” level of the bit line BLt, and the power supply voltage VDD (“H”) is supplied to the bit line BLb. Meanwhile, the pMOS transistor P6 turns to an OFF state (non-conducting state) by application of the “H” level of the bit line BLb, and the power supply voltage VDD is not supplied to the bit line BLt.

In addition, if “L” is stored in the SRAM cell 10, the bit line BLb turns to “L”, and the bit line BLt turns to “H”. In this case, the pMOS transistor P7 turns to an OFF state by “H” of the bit line BLt, and the power supply voltage VDD is not supplied to the bit line BLb. Meanwhile, the pMOS transistor P6 turn to an ON state by “L” of the bit line BLb, and the power supply voltage VDD is supplied to the bit line BLt.

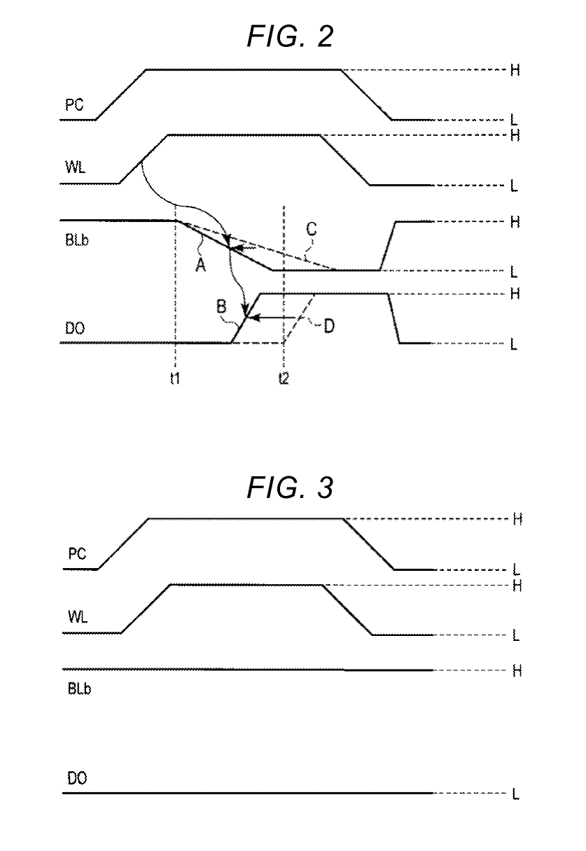

In addition, a reading operation of the semiconductor memory device according to the first embodiment will be described. FIGS. 2 and 3 are timing charts illustrating a reading operation according to the first embodiment. FIG. 2 illustrates a case where the “L” data is to be read out, and FIG. 3 illustrates a case where the “H” data is to be read out.

A case where the “L” data is read out will be described with reference to FIG. 2. Firstly, the precharge signal PC turns to “H”, and the pMOS transistors P3, P4, and P5 turn to an OFF state. As a result, the precharge circuit 11 is deactivated, and precharging the bit lines BLt and BLb is stopped.

Next, a potential of the word line WL becomes “H”, and the nMOS transistors N3 and N4 turn to an ON state. As a result, the “L” data that is stored in the SRAM cell 10 is read out to the bit line BLb. That is, as denoted by “A” in FIG. 2, the potential of the bit line BLb switches from “H” to “L”. At this time, since the potential of the bit line BLt is “H”, the pMOS transistor P7 in the reading circuit 12 turns to an OFF state. As a result, a supply of the power supply voltage VDD to the bit line BLb via the pMOS transistor P7 is stopped, and the bit line BLb rapidly switches from “H” to “L” levels.

Thereafter, the potential “L” of the bit line BLb turns to “H” via the inverter IV4 (“B” of FIG. 2), and is output as the output data DO.

Next, a case where the “H” data is read out will be described with reference to FIG. 3. Firstly, the precharge signal PC turns to “H”, and precharging the bit lines BLt and BLb is stopped.

Next, the word line WL goes to “H”, and the nMOS transistors N3 and N4 turns to an ON state. As a result, the “H” data that is stored in the SRAM cell 10 is read out to the bit line BLb. That is, as illustrated in FIG. 3, the potential of the bit line BLb is maintained as “H”. Here, in a reading period, the potential of the bit line BLb is required to be maintained as “H”. When the “H” data is stored in the SRAM cell 10, the bit line BLt goes to “L”. For this reason, the pMOS transistor P7 in the reading circuit 12 turns to an ON state. As a result, the power supply voltage VDD is supplied to the bit line BLb via the pMOS transistor P7, and the potential of the bit line BLb is maintained as “H”.

Thereafter, the potential “H” of the bit line BLb inverts to “L” via the inverter IV4, and is output as the output data DO.

In the first embodiment, the pMOS transistors P6 and P7, the gates of which are cross-coupled to the drains of which and the bit line, are included. When the “L” data stored in the SRAM cell 10 is read out, the potential “H” of the bit line BLt is input to the gate of the pMOS transistor P7, and thus the power supply voltage VDD is not supplied to the bit line BLb. As a result, the bit line BLb rapidly switches from “H” to “L”. Meanwhile, when the “H” data stored in the SRAM cell 10 is read out, the potential “L” of the bit line BLt is input to the gate of the pMOS transistor P7, and thus the power supply voltage VDD is supplied to the bit line BLb. As a result, even when the potential of the bit line BLb is decreased by a leakage current, the bit line BLb is maintained as “H”. By such operations, a rapid and correct reading operation with respect to the SRAM cell may be performed.

In FIG. 2, as a comparative example, voltage waveforms of the bit lines BLb (dashed line C) and the output data DO (dashed line D) in a case where a keeper circuit is used for maintaining the “H” data of the bit line BLb are illustrated. In the comparative example, the keeper circuit continually supplies the power supply voltage VDD to the bit line BLb, until the output data DO becomes “H”, and prevents the bit line BLb from switching from “H” to “L” from time t1 to time t2. For this reason, as denoted by “C” in FIG. 2, the potential of the bit line BLb only slowly switches from “H” to “L”. Thus, an operation during reading the “L” data becomes slower.

However, according to the first embodiment, when the “L” data is read out, the supply of the power supply voltage VDD to the bit line BLb is stopped, whereby the bit line BLb may rapidly switch from “H” to “L”. Furthermore, when the “H” data is read out, the power supply voltage VDD is supplied to the bit line BLb, whereby the bit line BLb may be maintained as “H”, even if there is a leakage current. As a result, a rapid and correct reading operation with respect to the SRAM cell may be performed.

### 2. Second Embodiment

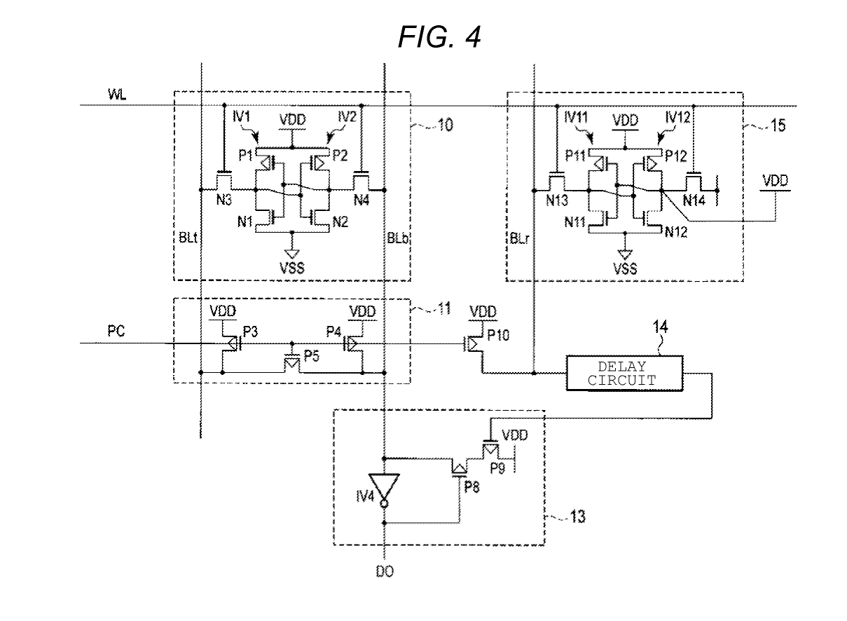

Next, a semiconductor memory device according to a second embodiment will be described. FIG. 4 is a circuit diagram illustrating a configuration of the semiconductor memory device according to the second embodiment. As illustrated in FIG. 4, the semiconductor memory device includes the SRAM cell 10, the precharge circuit 11, a reading circuit 13, a delay circuit 14, and an SRAM replica cell 15.

The SRAM cell 10 and the precharge circuit 11 are the same as those of the first embodiment.

The reading circuit 13 includes pMOS transistors P8 and P9, and an inverter IV4. A drain of the pMOS transistor P9 is connected to a source of the pMOS transistor P8. A drain of the pMOS transistor P8 is connected to the bit line BLb and an input portion of the inverter IV4. A gate of the pMOS transistor P8 is connected to an output portion of the inverter IV4. A gate of the pMOS transistor P9 is connected to the delay circuit 14. Furthermore, a source of the pMOS transistor P9 is connected to the power supply voltage VDD.

The SRAM replica cell 15 includes inverters IV11 and IV12 that have output portions and input portions which are cross-coupled to each other. The output portion of the inverter IV11 is connected to a replica bit line BLr via a current path of an nMOS transistor N13. The output portion of the inverter IV12 is connected to a current path of an nMOS transistor N14. The SRAM replica cell 15 uses an SRAM cell that is the same as, for example, the SRAM cell 10. That is, the SRAM replica cell 15 has the same configuration as, for example, the SRAM cell 10, and is formed by the same fabrication processing as the SRAM cell 10.

The output portion of the inverter IV12 and sources of the pMOS transistors P11 and P12 are connected to the power supply voltage VDD. Sources of the nMOS transistors N11 and N12 are connected to the reference voltage Vss. Gates of the nMOS transistors N13 and N14 are connected to the word line WL. The nMOS transistors N13 and N14 turn to an ON state or an OFF state by a potential of the word line WL, and serve as transmission transistors. Furthermore, the replica bit line BLr is connected to a gate of the pMOS transistor P9 via the delay circuit 14.

Next, a reading operation of the semiconductor memory device according to the second embodiment will be described.

A case where the “L” data is read out will be described with reference to FIG. 2. Firstly, the precharge signal PC goes to “H”, and the pMOS transistors P3, P4, P5, and P10 turn to an OFF state. As a result, precharging the bit lines BLt, BLb, and BLr is stopped.

Next, the potential of the word line WL becomes “H”, and the nMOS transistors N3 and N4 turns to an ON state. As a result, the “L” data that is stored in the SRAM cell 10 is read out to the bit line BLb. That is, as denoted by “A” in FIG. 2, the potential of the bit line BLb switches from “H” to “L”.

The power supply voltage VDD (“H”) is supplied to the output portion of the inverter IV12 and the input portion of the inverter IV11 in the SRAM replica cell 15. For this reason, a potential of the output portion of the inverter IV11 is maintained as “L”. Here, if the potential of the word line WL becomes “H”, the nMOS transistors N13 and N14 also turn to an ON state. As a result, a potential “L” of the output portion of the inverter IV11 in the SRAM replica cell 15 is read out to the bit line BLr. That is, a potential of the bit line BLr switches from “H” to “L”. At this time, since the SRAM replica cell 15 has the same electrical characteristic as the SRAM cell 10, time that is necessary for the bit line BLr to switch from “H” to “L” is equal to the time that is necessary for the bit line BLb to switch from “H” to “L”. Furthermore, a signal voltage of the bit line BLr is delayed by the delay circuit 14 and is input to the gate of the pMOS transistor P9. For this reason, until the bit line BLb switches from “H” to “L”, the pMOS transistor P9 is maintained as an OFF state. As a result, the supply of the power supply voltage VDD to the bit line BLb via the pMOS transistors P8 and P9 is stopped, and as described above, the bit line BLb rapidly switches from “H” to “L”.

Thereafter, the potential “L” on the bit line BLb becomes “H” via the inverter IV4, and is output as the output data DO.

After the bit line BLr switches from “H” to “L”, the potential “L” of the bit line BLr is delayed by the delay circuit 14 and is input to the gate of the pMOS transistor P9. As a result, the pMOS transistor P9 turns to an ON state. At this time, since the bit line BLb is in an “L” state, the potential on the bit line BLb becomes the output data DO (“H”) via the inverter IV4. The output data DO (“H”) is input to the gate of the pMOS transistor P8, and the pMOS transistor P8 turns to an OFF state. Thus, in a reading period of the “L” data, the power supply voltage VDD is not supplied to the bit line BLb via the pMOS transistors P8 and P9.

Hereinafter, the description will be focused on the reading circuit 13. In a case where the “L” data is read out, when a reading operation is started, the pMOS transistor P9 turns to an OFF state, and the pMOS transistor P8 turns to an ON state. For this reason, the power supply voltage VDD is not supplied to the bit line BLb via the pMOS switches P8 and P9. Thereafter, while the bit line BLb switches from “H” to “L”, the output data DO switches from “L” to “H”, and thus, the pMOS transistor P8 is changed from an ON state to an OFF state.

The bit line BLr also switches from “H” to “L” in the same manner as the bit line BLb, but a signal voltage of the bit line BLr is delayed by the delay circuit 14, and thus before the output data DO becomes “H”, the potential “L” of the bit line BLr is not input to the gate of the pMOS transistor P9. Thus, in the reading period of the “L” data, a current that prevents the bit line BLb from switching from “H” to “L” is not supplied to the bit line BLb, and the bit line BLb rapidly switches from “H” to “L”.

Next, a case where the “H” data is read out will be described with reference to FIG. 3. Firstly, the precharge signal PC becomes “H”, the pMOS transistors P3, P4, P5, and P10 turn to an OFF state. As a result, precharging the bit lines BLt, BLb, and BLr is stopped.

Next, the potential of the word line WL becomes “H”, and the nMOS transistors N3 and N4 turn to an ON state. As a result, the “H” data that is stored in the SRAM cell 10 is read out to the bit line BLb. That is, as illustrated in FIG. 3, the potential of the bit line BLb is maintained as “H” as it is.

“H” is supplied to the output portion of the inverter IV12 and the input portion of the inverter IV11 in the SRAM replica cell 15. For this reason, the potential of the output portion of the inverter IV11 is maintained as “L”. Here, if the potential of the word line WL becomes “H”, the nMOS transistors N13 and N14 also turn to an ON state. As a result, the potential “L” of the output portion of the inverter IV11 in the SRAM replica cell 15 is read out to the bit line BLr. That is, the potential of the bit line BLr switches from “H” to “L”.

After the bit line BLr switches from “H” to “L”, the potential “L” of the bit line BLr is delayed by the delay circuit 14 and is input to the gate of the pMOS transistor P9. As a result, the pMOS transistor P9 turns to an ON state. At this time, since the potential of the bit line BLb is “H”, the supply of the power supply voltage VDD to the bit line BLb via the pMOS transistors P8 and P9 is started, and the potential of the bit line BLb is maintained as “H”.

The potential “H” of the bit line BLb becomes “L” via the inverter IV4, and is output as the output data DO.

Hereinafter, the description will be focused on the reading circuit 13. In a case where the “H” data is read out, when a reading operation is started, the pMOS transistor P9 turns to an OFF state, and the pMOS transistor P8 turns to an ON state. For this reason, the power supply voltage VDD is not supplied to the bit line BLb via the pMOS transistors P8 and P9. Thereafter, since the bit line BLb is maintained as “H”, and the output data DO is also maintained as “L”, the pMOS transistor P8 is maintained in an ON state.

The potential of the bit line BLr switches from “H” to “L”, is delayed by the delay circuit 14, and is input to the gate of the pMOS transistor P9. As a result, the pMOS transistor P9 turns to an ON state. As a result, during a reading operation of the “H” data, the power supply voltage VDD is supplied to the bit line BLb via the pMOS transistors P8 and P9, and the potential of the bit line BLb is maintained as “H”.

The second embodiment includes the SRAM replica cell that replicates displacement of the bit line potential, and the delay circuit that delays the signal voltage of the bit line. When the “L” data is read out, the supply of the power supply voltage VDD to the bit line BLb is stopped, whereby the bit line BLb may rapidly switch from “H” to “L”. Furthermore, when the “H” data is read out, the power supply voltage VDD is supplied to the bit line BLb, whereby the bit line BLb may be maintained as “H” even if there is a leakage current. As a result, a rapid and correct reading operation with respect to the SRAM cell may be performed.

As described above, according to the first and second embodiments, it is possible to provide a semiconductor memory device that may speed up the reading operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory cell including:
a first inverter having a first input and a first output, and
a second inverter having a second input connected to the first output and a second output connected to the first input;
a first bit line connected to the first output via a first transmission transistor;
a second bit line connected to the second output via a second transmission transistor;
a first p channel metal-oxide-semiconductor (MOS) transistor having a drain connected to the first bit line and a gate connected to the second bit line; and
a second p channel MOS transistor having a drain connected to the second bit line and a gate connected to the first bit line.

2. The device according to claim 1, wherein a source of the second p channel MOS is connected to a power supply voltage, and
when a second voltage of the second bit line is higher than a first voltage of the first bit line, the second p channel MOS transistor turns to an ON state

3. The device according to claim 1, wherein a source of the second p channel MOS is connected to a power supply voltage, and
when a second voltage of the second bit line is lower than a first voltage of the first bit line, the second p channel MOS transistor turns to an OFF state.

4. The device according to claim 1, further comprising:
a third inverter having an input connected to the first bit line; and
a fourth inverter having an input connected to the second bit line.

5. The device according to claim 1, wherein the memory cell is a static-random access memory (SRAM) cell.

6. The device according to claim 1, further comprising:
a third p channel metal-oxide-semiconductor (MOS) transistor having a drain connected to the first bit line, a source connected to a power supply voltage, and a gate connected to a precharge signal line;
a fourth p channel metal-oxide-semiconductor (MOS) transistor having a drain connected to the second bit line, a source connected to the power supply voltage, and a gate connected to the precharge signal line; and
a fifth p channel metal-oxide-semiconductor (MOS) transistor connected between the first and second bit lines and having a gate connected to the precharge signal line.

7. The device according to claim 1, wherein
the first inverter comprises:
a third p channel metal-oxide-semiconductor (MOS) transistor connected in series, drain to drain, with a first n channel metal-oxide-semiconductor (MOS) transistor between a power supply voltage and a reference voltage, gates of the first n channel MOS transistor and the third p channel MOS transistor being connected to the second output; and
the second inverter comprises:
a fourth p channel metal-oxide-semiconductor (MOS) transistor connected in series, drain to drain, with a second n channel metal-oxide-semiconductor (MOS) transistor between a power supply voltage and a reference voltage, gates of the first n channel MOS transistor and the third p channel MOS transistor being connected to the first output.

8. The device according to claim 1, wherein
the first transmission transistor is a first n-channel MOS transistor having a gate connected to a word line of the memory cell; and
the second transmission transistor is a second n-channel MOS transistor having a gate connected to the word line of the memory cell.

9. A semiconductor memory device, comprising:
a first memory cell including:
a first inverter having a first input and a first output, and
a second inverter having a second input connected to the first output and a second output connected to the first input;
a first bit line connected to the first output via a first transmission transistor;
a second bit line connected to the second output via a second transmission transistor;
a second memory cell including:
a third inverter having a third input and a third output, and
a fourth inverter having a fourth input connected to the third output and a fourth output connected to third input, the fourth output connected to a power supply voltage;
a third bit line connected to the third output via a third transmission transistor;
a delay circuit configured to delay a signal voltage supplied on the third bit line and having an delay signal output at which the signal voltage is output as a delayed signal voltage after a predetermined delay period;
a fifth inverter having an input connected to the second bit line;
a first p channel metal-oxide-semiconductor (MOS) transistor having a gate connected to the delay signal output and a source connected to the power supply voltage; and
a second p channel MOS transistor having a source connected to a drain of the first p channel MOS transistor, a drain connected to the second bit line, and a gate connected to an output of the fifth inverter.

10. The device according to claim 9, further comprising:
a third p channel MOS transistor having a drain connected to the first bit line, a source connected to the power supply voltage, and a gate connected to a precharge signal line;
a fourth p channel MOS transistor having a drain connected to the second bit line, a source connected to the power supply voltage, and a gate connected to the precharge signal line;
a fifth p channel MOS transistor connected between the first and second bit lines and having a gate connected to the precharge signal line; and
a sixth p channel MOS transistor having a drain connected to the third bit line, a source connected to the power supply voltage, and a gate connected to the precharge signal line.

11. The device according to claim 9, wherein
the first transmission transistor has a gate connected to a word line,
the second transmission transistor has a gate connected to the word line, and
the third transmission transistor has a gate connected to the word line.

12. The device according to claim 9, wherein the first, second, and third transmission transistors are each n channel metal-oxide-semiconductor (MOS) transistors.

13. The device according to claim 12, wherein
the first transmission transistor has a gate connected to a word line,
the second transmission transistor has a gate connected to the word line,
the third transmission transistor has a gate connected to the word line, and
when the word line has a voltage level greater than a threshold voltage level of each of the first, second, and third transmission transistor, a first voltage level on the first bit line changes in correspondence with data stored in the first memory cell, a second voltage level on the second bit line changes in correspondence with data stored in the first memory cell, the first and second levels changing in complementary directions, and a third voltage level on the third bit line decreases to a fourth voltage level.

14. The device according to claim 9, wherein the second memory cell is a replica cell having electrical characteristics corresponding to the first memory cell.

15. A memory device, comprising:
a first static-random access memory (SRAM) cell connected to a word line and a complementary pair of bit lines;
a precharging circuit configured to charge the complementary pair of bit lines to a first voltage level in response to a precharging signal; and
a reading circuit connected to a first bit line in the complementary pair of bit lines and configured to connect the first bit line to a power supply voltage when the first bit line has a first bit line voltage level that is equal to or greater than the first voltage level and to disconnect the first bit line from the power supply voltage when the first bit line has the first bit line voltage level that is less than the first voltage level.

16. The memory device according to claim 15, wherein the reading circuit comprises:
a first p channel metal-oxide-semiconductor (MOS) transistor having a drain connected to a second bit line in the complementary pair of bit lines, a source connected to the power supply voltage, and a gate connected to the first bit line; and
a second p channel MOS transistor having a drain connected to the first bit line, a source connected to the power supply voltage, and a gate connected to the second bit line.

17. The memory device according to claim 15, further comprising:
a second SRAM cell connected to the word line and a third bit line that is not in the complementary pair of bit lines, the second SRAM cell being a replica cell having electrical characteristics corresponding to the first SRAM cell and configured to output a signal voltage on the third bit line which changes from the first voltage level to a second voltage level that is lower than the first voltage level when the word line is at a high level; and
a delay circuit configured to delay the signal voltage and then output signal voltage as a delayed signal voltage after a predetermined delay period, wherein
the reading circuit comprises:
an inverter having an input connected to the first bit line;
a first p channel MOS transistor having a gate configured to receive the delayed signal voltage and a source connected to the power supply voltage; and
a second p channel MOS transistor having a source connected to a drain of the first p channel MOS transistor, a drain connected to the first bit line, and a gate connected to an output of the inverter.

18. The memory device according to claim 17, further comprising:
a third p channel MOS transistor having a drain connected to the third bit line, a source connected to the power supply voltage, and a gate connected to a precharge signal line on which the precharge signal is supplied.

19. The memory device according to claim 15, wherein the first SRAM cell is a six transistor SRAM cell.

20. The memory device according to claim 15, wherein the precharging circuit comprises:
a first p channel MOS transistor having a drain connected to a second bit line in the complementary pair of bit lines, a source connected to the power supply voltage, and a gate connected to a precharge signal line;
a second p channel MOS transistor having a drain connected to the first bit line, a source connected to the power supply voltage, and a gate connected to the precharge signal line; and
a third p channel MOS transistor connected between the first and second bit lines and having a gate connected to the precharge signal line.
